(19) United States
(12) Patent Application Publication
(10) Pub. No.: US 2007/0029570 A1
(43) Pub. Date: Feb. 8, 2007

(54) LED package and method for fabricating the same

(75) Inventors: Su-ho Shin, Seongnam-si (KR); Kyu-ho Shin, Seoul (KR); Soon-cheol Kweon, Seoul (KR); Chang-youl Moon, Suwon-si (KR); Jin-seung Choi, Suwon-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/407,276

(22) Filed: Apr. 20, 2006

(30) Foreign Application Priority Data
Aug. 4, 2005 (KR) 2005-0071366

(51) Int. Cl. H01L 33/00

(52) U.S. Cl. 257/99

(57) ABSTRACT

An LED package comprises: a package body having therein a LED receiving part including a reflecting surface; an LED mounted within the LED receiving part; a lead mounted within the package body such that first and second ends of the lead are exposed to the outside of the package body. The lead includes first and second conductive parts which are electrically connected to the LED and a non-conductive part which insulates the first and second conductive parts from each other.

### CROSS-REFERENCE TO RELATED APPLICATIONS

This application claims the benefit of Korean Patent Application No. 2005-71366 filed Aug. 4, 2005 in the Korean Intellectual Property Office, the disclosure of which is incorporated herein by reference.

### BACKGROUND OF THE INVENTION

1. Field of the Invention

Apparatuses and methods consistent with present invention relate to a light emitting diode (LED) package and a manufacturing method thereof, which can be used for illumination or as a back light unit of a liquid crystal display (LCD) or the like.

2. Description of the Related Art

LEDs are widely employed not only in the electric and electronic fields but also in the advertisement field due to their advantages in terms of long life and low power consumption. Attempts to employ LEDs, for example, as backlight units of LCDs, have been made recently, and the LEDs may be widely employed in indoor and outdoor illumination systems in the future. Therefore, an interest in compact LED packages which can easily dissipate heat has increased.

In order to employ an LED as a backlight unit of an LCD display or in illumination system, high power is required. However, because the performance of such an LED is exponentially reduced as temperature increases, heat dissipation is also important.

FIG. 1 is a cross-sectional view of an exemplary conventional LED package. As shown in FIG. 1, the LED package comprises an LED 1, a heat spreading member 2, on which the LED 1 is mounted, leads 3 and 3′, wires 4 and 4′ for electrically connecting the LED and the leads 3 and 3′, and a body 5 for enclosing the heat sink 2 and the leads 3 and 3′.

The body 5 leaves the heat spreading member 2 exposed at its top and bottom sides, and an insulation layer 6 is disposed on the top side of the heat spreading member 2. The LED 1 is bonded to a central portion of the insulation layer 6 by an adhesive layer 7, and first ends of the leads 3 and 3′ are laid atop of the insulation layer 6 adjacent to opposite edges of the insulation layer 6. The second ends of the leads 3 and 3′ outwardly project from opposite lateral edges of the body 5. The wires 4 and 4′ are provided to connect the LED 1 and the first ends of the leads 3 and 3′. Although not shown in the drawing, a cap for sealing the LED 1 may be provided on top of the body 5.

The above-mentioned conventional LED package is mounted on a substrate 10 by soldering the second ends of the leads 3 and 3′ to pads 11 and 11′ formed on the substrate 10. In addition, solder 12 is disposed between the heat spreading member 2 of the LED package and the substrate 10, so that the heat generated by the LED 1 can be outwardly dissipated through the heat spreading member 2, the solder 12, and the substrate 10.

The above-described conventional LED package has poor heat dissipation properties because it has a relatively long heat transfer path formed by contact between different materials (LED→insulation layer→heat spreading member→substrate), whereby thermal resistance increases. Therefore, it is not suitable for packaging a high power LED.

Specifically, thermal resistance Rₜₕ can be expressed by the following equation: Rₜₕ=L/(k*A). According to this equation, thermal resistance Rₜₕ can be reduced if the thickness or the heat transfer path L is reduced and the thermal conductivity k and the heat dissipation area A are increased. However, the thermal resistance of the above-mentioned conventional LED package is naturally high because it has contact parts formed from different materials and because the heat transfer path of the LED package is long due to the thicknesses of the package and the substrate.

If the heat dissipation performance of an LED package is poor, the life of the LED will be shortened. Furthermore, it may cause fatal damage to a system because parts around the LED package may deteriorate and become thermally deformed due to the high temperature of the LED package.

In addition, the manufacture of the above-described LED package requires a separate step of bonding wires. Furthermore, when an LED array module is configured using such LED packages, a step of soldering the packages on a substrate is also required. Accordingly, there is a problem in that the number of assembling steps is increased and thus the manufacturing costs are also increased.

Moreover, the step of interconnecting the electrodes and leads with conducting wires becomes more difficult as electrode patterns on LEDs become more complicated in order to improve the optical efficiency and performance of the LED.

### SUMMARY OF THE INVENTION

Accordingly, the present invention has been made to solve the above and other problems occurring in the prior art, and an exemplary object of the present invention is to provide an LED package having superior in heat dissipation performance, which is suitable for packaging a high power LED package, and which is simple in construction, whereby the LED package can be applied to an LED with a complicated electrode structure.

In order to achieve the above-mentioned and other exemplary objects of the present invention, an LED package comprises: a package body having therein an LED receiving part including a reflecting surface; an LED mounted within the LED receiving part; and a lead mounted within the package body such that first and second ends of the lead are exposed to the outside of the package body. The lead comprises first and second conductive parts electrically connected to the LED and a non-conductive part which insulates the first and second conductive parts from each other.

The package body may comprise a base member, and a reflecting member mounted on top of the base member with the lead being disposed between the base member and the reflecting member, wherein the LED receiving part is formed in the reflecting member.

The mounting part is formed in at least one of a surface of the base member facing the reflecting member and a surface of the reflecting member facing the base member.

The base member and the reflecting member may comprise a thermally conductive material and may be insulated from the first and second conductive parts by the non-conductive part.

According to an exemplary embodiment of the present invention, the first conductive part may comprise a first electrode part which is exposed to the LED receiving part and which is electrically connected to the LED, and a first external terminal which is exposed to the outside of the package body. The second conductive part may comprise a second electrode part which is exposed to the LED receiving part and which is electrically connected to the LED, and a second external terminal part which is exposed to the outside of the package body.

The first and second electrode parts may each have one or more exposed surface areas, which are spaced from each other and which are exposed to the LED receiving part and electrically connected to the LED.

The LED package may further comprise first and second metallic layers, formed on an external surface of the lead, which are electrically connected to the first and second electrode parts, respectively, wherein the first and second metallic layers are electrically connected with the LED.

The base member and the lead may be bonded to one another by an adhesive.

The LED package may further comprise a lens mounted over the LED receiving part.

The LED may be electrically connected to the first and second conductive parts through solder.

According to another exemplary aspect of the present invention, there is provided a method of fabricating an LED package comprising steps of: a) providing a package body comprising an LED receiving part therein and a lead mounting part, which communicates with the LED receiving part; b) fabricating a lead comprising first and second conductive parts, and a non-conductive part which insulates the conductive parts from each other and from the package body; c) mounting the lead on the lead mounting part of the package body such that the first and second conductive parts are exposed to the LED receiving part; and d) mounting an LED on the LED receiving part such that the LED is electrically connected to the first and second conductive parts when the LED is received in the LED receiving part.

Step a) may comprise: a1) providing a base member comprising a thermally-conductive material; a2) providing a reflecting member and bonding the reflecting member to the base member with the lead interposed therebetween, wherein the LED receiving part is formed through the reflecting member; and a3) forming the lead mounding part on one of a surface of the base member facing the reflecting member and a surface of the reflecting member facing the base member.

Step b) may comprise: b1) partially converting first predetermined areas of the metallic substrate into non-conductive areas by oxidation, thereby forming the non-conductive part and insulating first and second conductive parts from each other; b2) partially converting second predetermined areas of the metallic substrate into non-conductive areas through oxidation, thereby forming first and second electrode parts, which are electrically connected to the LED and which are insulated from the package body, and first and second external terminal parts, which are electrically connected to the first and second electrode parts and which are insulated from the package body; and b3) patterning and forming metallic layers on the first and second electrode parts exposed to the outside of the metallic substrate.

Step c) may comprise: c1) bonding the lead to the lead mounting part using an adhesive; and c2) bonding the base member and the reflecting member to each other with the lead interposed therebetween. In addition, conductive adhesive may be used to bond the lead to the lead mounting part and to bond the base member to the reflecting member.

The package body may comprise a metallic material, and the first and second conductive parts may comprise aluminum or an aluminum alloy.

According to exemplary another aspect of the present invention, a method of fabricating LED packages comprises: a) providing a plurality of package bodies each comprising an LED receiving part therein and a lead mounting part, which communicates with the LED receiving part; b) fabricating a plurality of leads on a metallic substrate, each of the plurality of leads comprising first and second conductive parts, and a non-conductive part which insulates the first and second conductive parts from each other and from the package body; c) bonding the plurality of leads to the lead mounting parts of the plurality of package bodies such that each lead is mounted on a corresponding lead mounting part of one of the plurality of package bodies; d) mounting plurality of LEDs in the LED receiving parts such that each of the plurality of LEDs is electrically connected to corresponding first and second conductive parts when the LEDs are respectively received in the LED receiving parts; and e) separating the plurality of leads from the metallic substrate.

Step a) may comprise: a1) providing plurality of base members comprising a thermally conductive material; a2) providing plurality of reflecting members and bonding the plurality of reflecting members to the plurality of base members with the leads interposed therebetween, wherein each of the LED receiving parts is formed through a corresponding reflecting member; and a3) forming each of the lead mounting parts on one of a surface of a corresponding base member facing a corresponding reflecting member and a surface of a corresponding reflecting member facing a corresponding base member.

Step b) may comprise: b1) partially converting first predetermined areas of a metallic substrate into non-conductive areas through oxidation, thereby forming the non-conductive part and separating the first and second conductive parts of each of the plurality of leads, wherein the first and second conductive parts are insulated from each other; b2) partially converting second predetermined areas of the metallic substrate into non-conductive areas through oxidation, thereby forming first and second electrode parts for each LED package, which are electrically connected to a corresponding LED and which are insulated from a corresponding package body, and first and second external terminal parts of the corresponding LED package, which are electrically connected to the first and second electrode parts of the corresponding LED package and which are insulated from the corresponding package body; b3) patterning and forming metallic layers on the first and second electrode parts, which are exposed to the outside of the metallic substrate; and b4) partially removing the metallic substrate, such that the plurality of leads are spaced from each other.

Step c) may comprise: c1) bonding the plurality of leads to the lead mounting parts, respectively, by using an adhesive; and c2) bonding the base members and the reflecting members to each other with the leads interposed therebetween.

A conductive adhesive may be used to bond the plurality of leads to the lead mounting parts and to bond the base members to the reflecting members.

In step b4), the metallic substrate may be punched such that a width of the first external terminal parts where they are in contact with the package body is different than a width of the second external terminal ports where they are in contact with the package body.

### BRIEF DESCRIPTION OF THE DRAWINGS

The above and other exemplary aspects of the present invention will become more apparent from the following detailed description of exemplary embodiments of the present invention taken with reference to the accompanying drawings, in which:

FIG. 1 is a cross-sectional view of an exemplary conventional LED package;

FIG. 2 is an exploded perspective view of an LED package according to an exemplary embodiment of the present invention;

FIG. 3A is a cross-sectional view of the LED package of FIG. 2 in an assembled state;

FIG. 3B is a top plan view of a main part extracted from the LED package of FIG. 3A;

FIG. 3C is a cross-sectional view taken along line I-I in FIG. 3B;

FIGS. 4A to 4F are cross-sectional views of an exemplary process of fabricating a lead of an exemplary LED package according to the present invention;

FIGS. 5A and 5B are cross-sectional views of another exemplary process of fabricating a lead of an exemplary LED package according to the present invention;

FIGS. 6A to 6D are perspective views of an exemplary method of fabricating the inventive leads in large quantities;

FIG. 7 is a schematic cross-sectional view showing a lead according to another exemplary embodiment of the present invention;

FIG. 8 is a schematic cross-sectional view showing a reflecting member according to another exemplary embodiment of the present invention;

FIG. 9A is a top plan view showing a lead according to another exemplary embodiment of the present invention;

FIG. 9B is a cross-sectional view taken along line II-II of FIG. 9A;

FIG. 9C is a cross-sectional view taken along line III-III of FIG. 9A;

FIG. 10A is a top plan view showing a lead according to another exemplary embodiment of the present invention;

FIG. 10B is a cross-sectional view taken along line IV-IV of FIG. 10A; and

FIG. 10C is a cross-sectional view taken along line V-V of FIG. 10A.

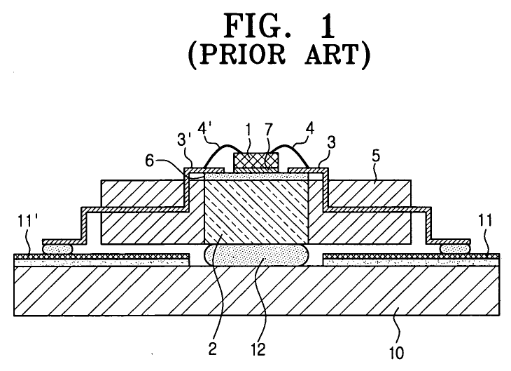

### DETAILED DESCRIPTION OF EXEMPLARY EMBODIMENTS OF THE PRESENT INVENTION

Hereinbelow, exemplary embodiments of the present invention are described in detail with reference to accompanying drawings. In the following description, detailed descriptions of known functions and configurations will be omitted when it may make the subject matter of the present invention rather unclear.

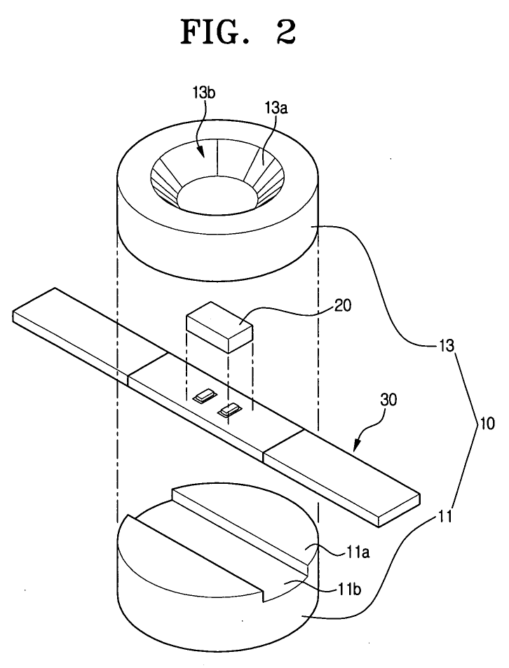

Referring to FIG. 2, an LED package according to a first exemplary embodiment of the present invention comprises a package body 10, an LED 20, and a lead 30, on which the LED is mounted and which is bonded to the package body 10.

The package body 10 comprises a base member 11 and a reflecting member 13 mounted on the base member 11. The base member 11 has a substantially circular cross-section and is formed from a metallic material having superior heat conductivity. A surface 11a of the base member 11, facing the reflecting member 13, includes a lead mounting part 11a. The lead mounting part 11b is formed by etching a portion of the surface 11a of the base member 11 to a predetermined depth.

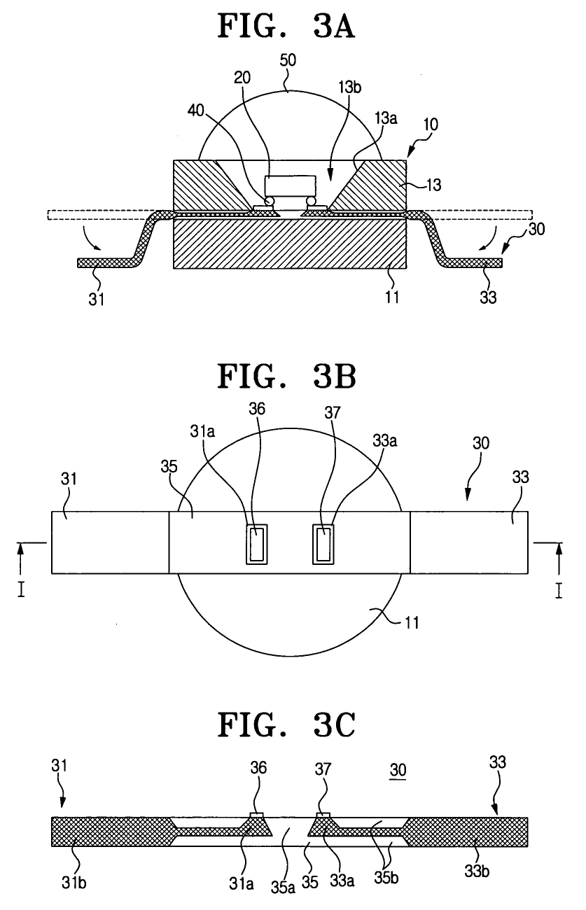

The reflecting member 13 is similar in shape to the base member 11 and also has a circular cross-section. The reflecting member 13 has an LED receiving part 13b for receiving the LED 20. A light reflecting surface 13a is formed in the receiving part 13b. As shown in FIG. 3A, the LED receiving part 13b is a vertical hole through the reflecting member 13. The reflecting surface 13a forms the internal peripheral surface of the LED receiving part 13b, the inner diameter of which gradually increases with distance from the LED. The thickness of the reflecting member 13 (and the depth of the receiving part 13b) is greater than the height of the LED 20 so that the LED 20 can be fully received within the LED receiving part 13b. The reflecting member 13 may also be a metallic material.

At least one side of the LED 20 has one or more electrodes formed thereon, which are electrically connected to the lead 30 by solder 40 through flip-chip bonding.

The lead 30 is electrically connected to the LED 20 such that the lead 30 is disposed between the base member 11 and the reflecting member 13. As shown in more detail in FIGS. 3B and 3C, the lead 30 has first and second conductive parts 31 and 33, and a non-conductive part 35 which insulates the first and second conductive parts 31 and 33 from each other.

The conductive parts 31 and 33 and the non-conductive part 35 are integrally formed as a single piece. The non-conductive part 35 is formed by converting a metal part, which is integral with the conductive parts 31 and 33, into a non-conductor by partially oxidizing the metal part.

The first conductive part 31 has a first electrode part 31a, which is electrically connected with the LED 20, and a first external terminal part 31b, which is electrically connected to the first electrode part 31a and which extends outside of the package body 10. The first electrode part 31a is partially exposed at the top surface of the lead 30, i.e., to the LED receiving part 13b, and the remaining part of the first electrode part 31a is insulated from the outside by the non-conductive part 35. The first external terminal part 31b is provided in order to connect the LED package with a terminal formed on a circuit board when the LED package is mounted on the circuit board.

The second conductive part 33 has a second electrode part 33a, which is electrically connected to the LED 20 and a second external terminal part 33b which is electrically connected to the second electrode part 33a.

The second electrode part 33a is insulated from the first electrode part 31a by the non-conductive part 35 and is partially exposed at the top side of the lead 30, so that the second electrode part 33a can be electrically connected to the LED 20. The second electrode 33a is electrically insulated from the package body 10 by being wrapped by the non-conductive part 35. The second external terminal part 33b is electrically connected to the second electrode part 33a and faces the first external terminal part 31b. The second terminal part 33b is also exposed outside of the package body 10. The lead 30 is seated on the mounting part 11b of the base member 11. Because the contact part between the lead 30 and the base member 11 correspond to the non-conductive part 35, the first and second conductive parts 31 and 33 can be assembled in an insulated state. When the lead 30 is bonded to the base member 11 and to the reflecting member 13, an adhesive having good thermal conductivity (e.g., a soldering material, such as silver-epoxy (Ag-epoxy), silver paste, gold-tin (Au—Sn), or lead-tin (Pb—Sn)) can be used.

More specifically, the non-conductive part 35 can be divided into a first insulation part for insulating the first and second conductive parts 31 and 33 from each other, and a second insulation part 35b for insulating the first and second conductive parts 31, 33 from the package body 10. The first insulation part 35a is formed by oxidizing a predetermined area of the lead 30 to a thickness corresponding to the thickness of the lead 30. The second insulation part 35b is formed on top and bottom surfaces of the lead 30 to a predetermined thickness. The second insulation part 35b can be formed by a secondary oxidation process after the first insulation part 35a is formed by a first oxidation process.

The first and second conductive parts 31 and 33 of the lead 30 configured as described above are formed from metal and integrally formed with the non-conductive part 35 as a single component. The non-conductive part 35 may be formed from an oxide of the metallic material of the first and second conductive parts 31 and 33. The first and second conductive parts 31 and 33 of the lead 30 may be formed from aluminum or an aluminum alloy, and the non-conductive part 35 may consist of aluminum oxide (Al₂O₃) which is formed by oxidizing a predetermined area of the aluminum or aluminum alloy substrate of the first and second conductive parts so that a predetermined area becomes non-conductive.

According to an exemplary embodiment of the present invention, first and second metallic layers 36 and 37 are formed and are adapted to be electrically connected with the first and second electrode parts 31a and 33a. The first and second metallic layers 36 and 37 are formed by patterning a metallic material on the external surface of the lead 30 to a predetermined thickness. The LED 20 is electrically connected to the upper surfaces of the metallic layers 36 and 37 by solder 40. The first and second metallic layers 36 and 37 may be formed through vapor-depositing, sputtering, or plating and may comprise at least one of aluminum (Al), copper (Cu), platinum (Pt), silver (Ag), titanium (Ti), chromium (Cr), gold (Au), and nickel (Ni), in a single layer or as a composite of layers.

Hereafter, a method of fabricating an LED package according to an exemplary embodiment of the present invention is described in detail with reference to accompanying drawings.

A lead mounting part 11b is formed on the base member 11 by etching, and a lead receiving part 13b is formed in the reflecting member 13b.

The lead 30 is fabricated by a method described below in detail.

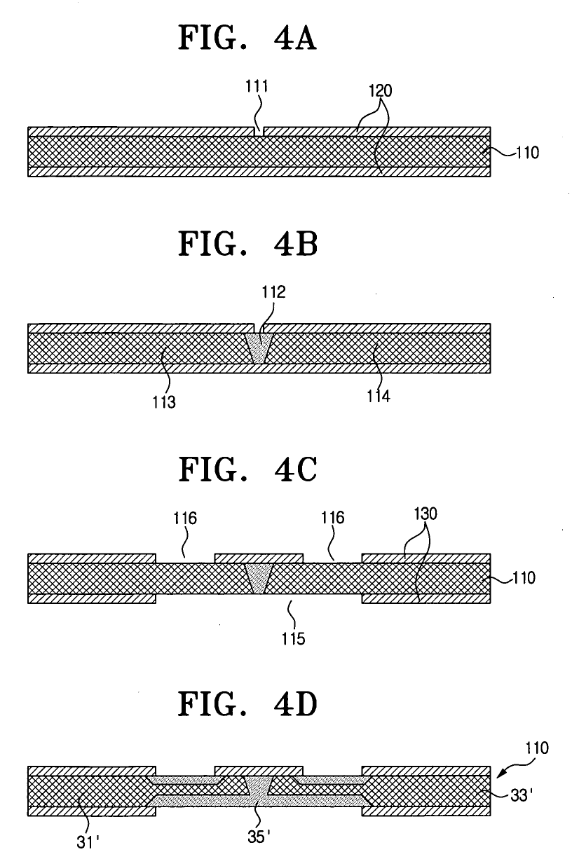

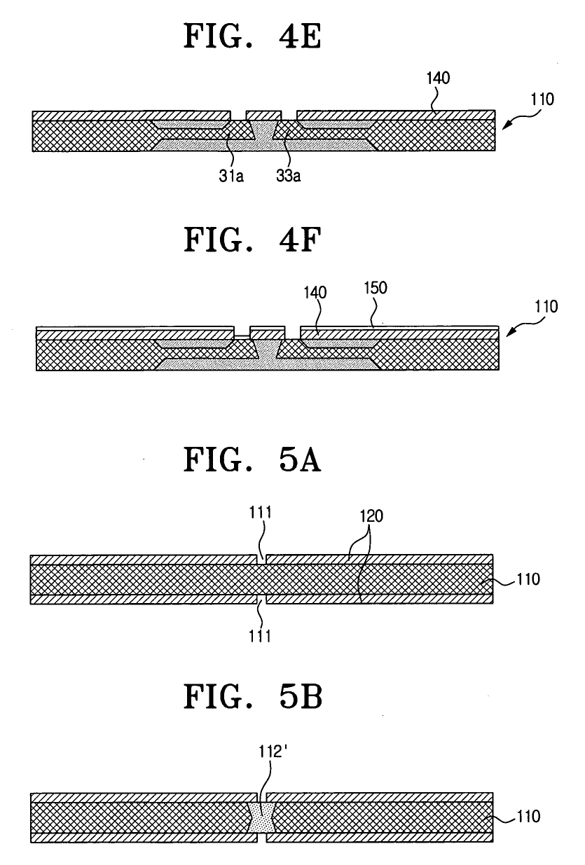

As shown in FIG. 4A, masks 120 are patterned on the top and bottom surfaces of a metallic substrate 110, which is the base material of the lead, so that predetermined areas of the metallic substrate 110 are exposed.

As shown in FIG. 4B, the exposed areas 111 are partially converted into non-conductive areas through anodic oxidation, so that the metallic substrate 110 is divided into a pair of conductive parts 113 and 114 insulated from each other by the a non-conductive part 112. The non-conductive part 112 is non-conductive as a result of the oxidation of the metallic substrate. As shown in FIG. 4C, additional areas of the metallic substrate 110 are patterned to predetermined shapes using masks 130, so that predetermined parts 115 and 116 are exposed. The exposed areas 115 and 116 are subject to a secondary anodic oxidation as shown in FIG. 4D, thereby being partially converted into non-conductive areas. The result is that the metallic substrate 110 is formed having first and second conductive parts 31′ and 33′, which correspond to first and second conductive parts 31 and 33, respectively, and a non-conductive part 35′, as described with reference to FIG. 3C.

As shown in FIG. 4E, the upper surface of the metallic substrate 110 is patterned using a mask 140, so that the areas corresponding to the first and second electrode parts 31a and 33a are exposed.

As shown in FIG. 4F, a metallic material 150 is vapor-deposited on the patterned mask 140 and the mask 140 is removed, thus forming first and second metallic layers 36 and 37, as shown in FIG. 3C.

By repeatedly performing steps of mask-patterning and oxidizing the metallic substrate 100, it is possible to form the conductive parts and the non-conductive part in the metallic substrate 110. Thereafter, a metallic layer is formed on the oxidized metallic substrate through vapor deposition, sputtering, plating or the like, whereby a lead 30 as shown in FIG. 3C is easily fabricated.

The lead 30, fabricated as described above, is bonded to the lead mounting part 11b of the base member 11. A conductive adhesive, which is superior in thermal conductivity, may be used as the adhesive for bonding, as described above.

The reflecting member 13 is bonded to an upper surface of the base member 11 by the conductive adhesive. The LED 20 is bonded to the first and second metallic layers 36 and 37 using the solder 40, such that the electrodes provided on the bottom of the LED 20 are electrically connected to the first and second electrode parts 31a and 33a, respectively, whereby the packaging is completed. Because the base member 11 and the reflecting member 13 are formed from a metallic material, they can be adhered to one another by bonding or welding.

It is also possible to mount a lens 50 on the reflecting member 13 after the LED 20 is mounted, as shown in FIG. 3A. The lens 50 can be also adhered by bonding. Because the portions of the lead 30 which are exposed to the outside of the package body 10 can be bent and deformed, it is possible to connect the lead 30 to external terminals by bending the lead 30.

If the lead 30 is fabricated through an oxidation process as described above, it is possible to integrally form the first and second conductive parts 31 and 33 and the non-conductive part 35, as described above. Therefore, the process of fabricating the lead 30 is simplified and the lead 30 can be simply bonded to the package body 10, whereby the productivity can be improved.

In addition, because the lead 30 is completely insulated from the package body 10, it is possible to join the lead 30 using a conductive adhesive which is superior in thermal conductivity. As a result, it is possible to enhance the efficiency of heat dissipation when driving the LED 20.

In the above exemplary description with reference to FIGS. 4A and 4B, only the mask provided on the top of the metallic substrate 110 is patterned, whereby only the top of the metallic substrate 110 is exposed. However, this is merely exemplary. That is, as shown in FIGS. 5A and 5B, it is possible to form a non-conductive part 112′ by respectively patterning masks 120 provided on the upper and lower surfaces of the metallic substrate 110, thereby exposing predetermined areas on the top and bottom of the metallic substrate 110, and then oxidizing the exposed areas.

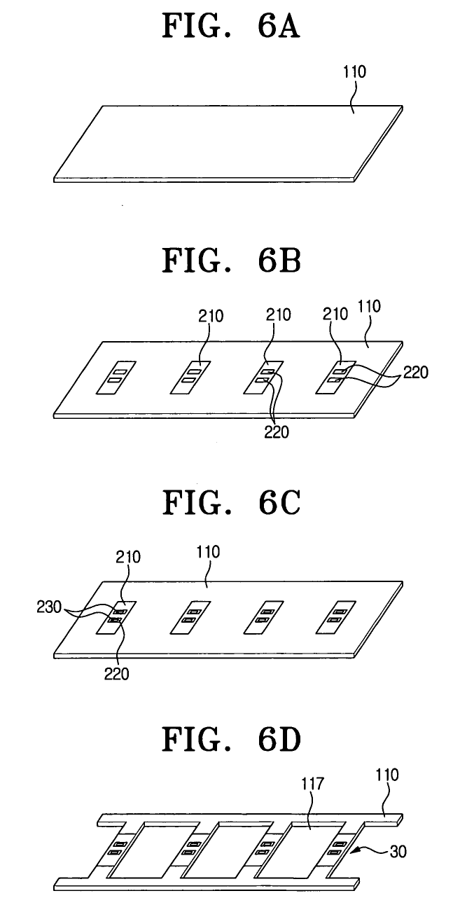

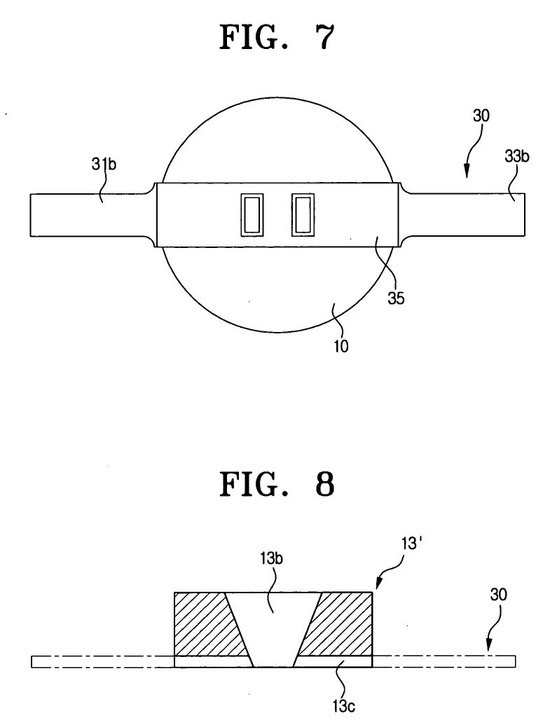

Now, a method of fabricating LED packages according to another exemplary embodiment of the present invention is described. In order to produce LED packages in large quantities, a metallic substrate 110, which is large enough to fabricate numerous leads, is provided, as shown in FIG. 6A. Then, a plurality of areas of the metallic substrate 110, which are spaced from each other, are converted into non-conductive areas through primary and secondary oxidation processes, as shown in FIG. 4A and 4B. In FIG. 6B, reference numeral 210 indicates the areas converted into non-conductive areas. Then, as shown in FIG. 6C, metallic layers 230 are formed on conductive areas partially exposed through the areas 210. The metallic layers 230 can be formed by using the methods described above with reference to FIGS. 4E and 4F.

As shown in FIG. 6D, predetermined areas of the metallic substrate 110 are removed by punching. In FIG. 6D, reference numeral 117 indicates the punched and removed areas. Due to the punched and removed areas, a plurality of individual leads 30 are provided, wherein the individual leads 30 are integrally connected with each other by the metallic substrate 110 such that they are spaced from each other by a predetermined distance.

After forming the plurality of leads 30, a package body 10 and an LED 20 are bonded to each of the leads 30, whereby a plurality of LED packages can be formed. Opposite ends of each lead 30 are cut, and each unit LED package is thus completed. Thus, by forming plural leads 30 at a time by using a single metallic substrate 11 0 and packaging LEDs 20 and package bodies 10 on the plural leads 30, respectively, manufacturing time can be shortened and mass production can be easily performed.

Additionally, when the metallic substrate 10 is punched so as to remove the predetermined areas as shown in FIG. 6D, it is possible to adjust the width and shape of each lead 30 by adjusting the shapes of the area to be removed from the metallic substrate 110.

For example, it is possible to form a lead 30 so that end portions of the lead 30 have a width narrower than that of a middle portion of the lead 30. Such a lead 30 can be fabricated by properly designing the areas to be removed by punching. If the width of the non-conductive part 35 adapted to come into contact with the package body 10 is increased, thereby increasing the contact area between package body 10 and the non-conductive part 35, the efficiency of transferring and dissipating heat can be improved.

Whereas, if the first and second external terminal parts 31b and 33b exposed to the outside of the package body 10 are formed more narrowly than the conductive part 35, it is possible to avoid contact between the first and second external terminal parts 31b and 33b and neighboring components or terminals, whereby problems caused by a narrow installation space can be overcome.

Although it has been described that the lead mounting part 11b is formed on the base member 11 (see e.g. FIG. 2), this is merely exemplary. Referring to FIG. 8, it is possible to form a lead mounting part 13c of a predetermined depth on a bottom surface of the reflecting member 13′.

In addition, although not show in the drawings, it is possible to form a lead mounting part on both the base member 11 and the reflecting member 13 to be bonded to one another, so that the lead 30 can be interposed between the members 11 and 13.

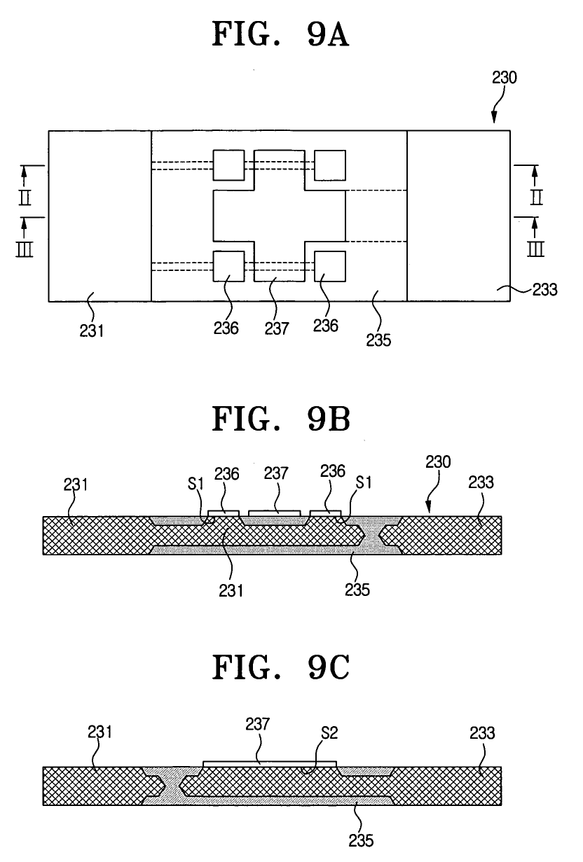

Referring to FIGS. 9A to 9C, at least one electrode part 231 may have a plurality of exposed surface areas S1, which are exposed outside the lead 230. The exposed surface areas S1 are separated on the external surface of the lead 230 and are insulated from the other electrode part 233 by the non-conductive part 235. In addition, a metallic layer 236, having a predetermined thickness, is formed on each of the plurality of exposed surface areas S1. Of course, the exposed surface area S2 of the other electrode part 233 is also formed with a metallic layer having a predetermined thickness. With this configuration, it is possible to form various electrode patterns, to which the LED 20 is electrically connected. Therefore, it is possible to work with recent LED chips, having complicated pad layouts and constructions so as to improve optical power. In particular, because it is possible to form the electrode part 233 on the non-conductive part 235 in a predetermined pattern within a range capable of being insulated from the other electrode part 231, the electrode part 233 can be also formed in various patterns. FIG. 9A shows a pattern structure formed by dispersing metallic layers 237 around one metallic layer 236.

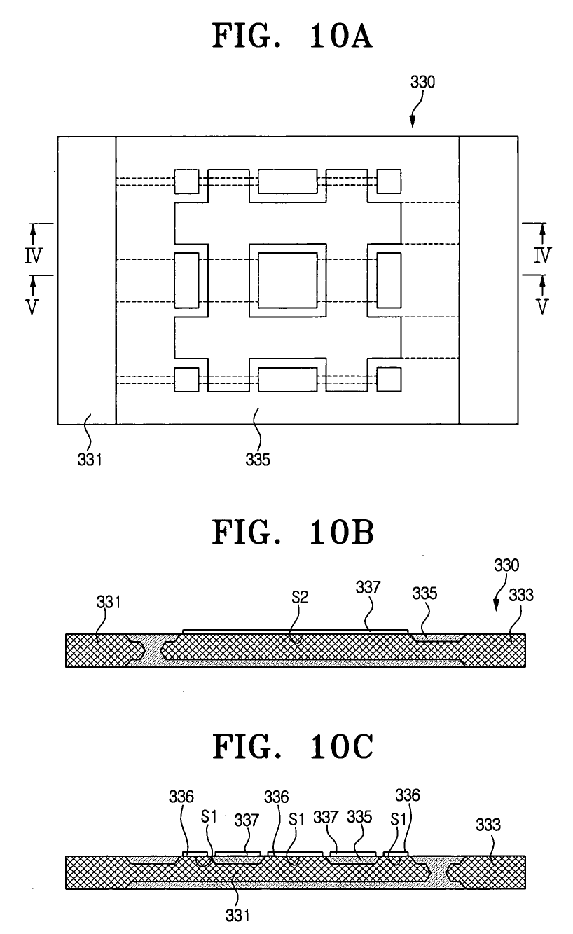

Also, it is possible to fabricate a lead 330 as shown in FIGS. 10A to 10C, which is configured so that an LED chip having so-called island type pads surrounded by other electrodes can be mounted on the lead 330.

Specifically, a plurality of exposed surface areas S1 are formed on the first electrode part 331 and then an exposed surface area S2 is formed on the second electrode part 333 adjacent to the exposed surface areas S1. Then, a metallic layer 336 of a predetermined thickness is formed on each exposed surface S1, so that a plurality of metallic layers 336 are structurally separated from each other at the external side of the electrode parts 331 and 333. Then, a metallic layer 337 is formed on the other exposed surface S2, wherein the metallic layer 337 is formed by patterning the external surface of the non-conductive part 335 in such a way that the metallic layer 337 at least partially surrounds the metallic layers 336. As a result, an electrode pattern as shown in FIG. 10A can be formed.

As described above, through steps of partially oxidizing a metallic substrate, and partially depositing metal on the oxidized metallic substrate, various types of electrode patterns can be formed. As a result, there is an advantage in that even the structurally complicated leads of an LED can be easily connected.

According to exemplary LED packages and a methods according to the present invention, it is possible to fabricate a thin and small LED which has superior heat dissipation performance. Therefore, a high power LED package employed for use in illumination systems or as a backlight unit of an LED display can be easily and inexpensively implemented, and an inexpensive, highly reliable LED array module can be easily provided.

In addition, because an LED can be packaged by flip-chip bonding without requiring electric connection through a conducting line such as a wire, the packaging can be easily performed. Further, because the packaging can be performed through bonding without a separate sub-mount for an LED with a complicated electrode pad structure, manufacturing costs can be reduced and productivity can be improved.

Furthermore, because electric signals can be applied to an LED with a single lead integrally formed with a non-conductive part, the number of components can be reduced, whereby the assemblability can be improved. In addition, because the LED is connected through a lead and solder, and the package body of the LED is formed from a metallic material, the heat generated when the LED is driven can be efficiently dissipated to the surrounding area.

Moreover, because a lead itself is provided with an insulation part, it is possible to use a highly conductive adhesive when interconnecting a lead and a package body, such that the heat dissipation performance can be improved.

Although certain exemplary embodiments of the present invention have been shown and described in order to exemplify the principles of the present invention, the present invention is not limited to the described and illustrated embodiments. It will be understood that various modifications and changes can be made by one skilled in the art without departing from the spirit and scope of the invention as defined by the appended claims. Therefore, it shall be considered that such modifications, changes and equivalents thereof are all included within the scope of the present invention.

What is claimed is:

1. A light emitting diode (LED) package comprising:
a package body having therein an LED receiving part including a reflecting surface;
an LED mounted within the LED receiving part;
a lead mounted within the package body such that first and second ends of the lead are exposed to the outside of the package body, wherein the lead comprises:
first and second conductive parts electrically connected to the LED, and
a non-conductive part which insulates the first and second conductive parts from each other.

2. An LED package as claimed in claim 1, wherein the package body comprises:
a base member; and
a reflecting member mounted on top of the base member;
wherein the lead is disposed between the base member and the reflecting member, and
wherein the LED receiving part is formed in the reflecting member.

3. An LED package as claimed in claim 2, wherein the base member has an upper surface facing the reflecting member and the reflecting member has a lower surface facing the base member, and
wherein at least one of the upper surface of the base member and the lower surface of the reflecting member has a mounting part formed therein in which the lead is disposed.

4. An LED package as claimed in claim 2, wherein the base member and the reflecting member comprise a thermally-conductive material and are insulated from the first and second conductive parts by the non-conductive part.

5. An LED package as claimed in claim 1, wherein the first and second conductive parts comprise a metallic material.

6. An LED package as claimed in claim 5, wherein the non-conductive part is an oxide of the metallic material forming the first and second conductive parts.

7. An LED package as claimed in claim 1, wherein the first and second conductive parts comprise aluminum or an aluminum alloy.

8. An LED package as claimed in claim 7, wherein the non-conductive part comprises an oxide of aluminum or of an aluminum alloy.

9. An LED package as claimed in claim 1,
wherein the first conductive part comprises a first electrode part which is exposed to the LED receiving part and which is electrically connected to the LED, and a first external terminal which exposed to the outside of the package body, and
wherein the second conductive part comprises a second electrode part which is exposed to the LED receiving part and which is electrically connected to the LED, and a second external terminal part which is exposed to the outside of the package body.

10. An LED package as claimed in claim 9, wherein the first and second electrode parts each have one or more exposed surfaces, which are exposed to the LED receiving part and which are electrically connected to the LED, wherein exposed surfaces of the first and second electrode parts are spaced from each other.

11. An LED package as claimed in claim 9, further comprising first and second metallic layers, formed on an external surface of the lead, which are electrically connected to the first and second electrode parts, wherein the first and second metallic layers are electrically connected with the LED.

12. An LED package as claimed in claim 2, wherein the base member and the lead are bonded to one another by an adhesive.

13. An LED package as claimed in claim 1, further comprising a lens mounted over the LED receiving part.

14. An LED package as claimed in claim 1, wherein the LED is electrically connected to the first and second conductive parts through solder.

15. A method of fabricating a light emitting diode (LED) package comprising:
a) providing a package body comprising an LED receiving part therein and a lead mounting part, which communicates with the LED receiving part;
b) fabricating a lead comprising first and second conductive parts, and a non-conductive part which insulates the conductive parts from each other and from the package body;
c) mounting the lead on the lead mounting part of the package body such that the first and second conductive parts are exposed to the LED receiving part; and
d) mounting an LED on the LED receiving part such that the LED is electrically connected to the first and second conductive parts when the LED is received in the LED receiving part.

16. A method as claimed in claim 15, wherein step a) comprises:
a1) providing a base member comprising a thermally-conductive material;
a2) providing a reflecting member and bonding the reflecting member to the base member with the lead interposed therebetween, wherein the LED receiving part is formed through the reflecting member; and
a3) forming the lead mounding part on one of a surface of the base member facing the reflecting member and a surface of the reflecting member facing the base member.

17. A method as claimed in claim 15, wherein step b) comprises:
b1) converting first predetermined areas of a metallic substrate into non-conductive areas by oxidation, thereby forming the non-conductive part and first and second conductive parts which are insulated from each other;
b2) partially converting second predetermined areas of the metallic substrate into non-conductive areas through oxidation, thereby forming first and second electrode parts, which are electrically connected to the LED and which are insulated from the package body, and first and second external terminal parts which are electrically connected to the first and second electrode parts and which are insulated from the package body; and
b3) patterning and forming metallic layers on the first and second electrode parts, which are exposed to the outside of the metallic substrate.

18. A method as claimed in claim 16, wherein step c) comprises steps of:
c1) bonding the lead to the lead mounting part using an adhesive; and
c2) bonding the base member and the reflecting member to each other with the lead interposed therebetween.

19. A method as claimed in claim 18, wherein a conductive adhesive is used to bond the lead to the lead mounting part and to bond the base member to the reflecting member.

20. A method as claimed in claim 16, wherein the package body comprises a metallic material.

21. A method as claimed in claim 15, wherein the first and second conductive parts comprise a metallic material.

22. A method as claimed in claim 21, wherein the non-conductive part comprises an oxide of the metallic material which forms the first and second conductive parts.

23. A method as claimed in claim 15, wherein the first and second conductive parts comprise aluminum or an aluminum alloy.

24. A method as claimed in claim 23, wherein the non-conductive part comprises an oxide of aluminum or of an aluminum alloy.

25. A method of fabricating light emitting diode (LED) packages comprising steps of:
a) providing a plurality of package bodies each comprising an LED receiving part therein and a lead mounting part, which communicates with the LED receiving part;
b) fabricating a plurality of leads on a metallic substrate, each of the plurality of leads comprising first and second conductive parts, and a non-conductive part which insulates the first and second conductive parts from each other and from the package body;
c) bonding the plurality of leads to the lead mounting parts of the plurality of package bodies such that each lead is mounted on a corresponding lead mounting part of one of the plurality of package bodies;
d) mounting a plurality of LEDs on the LED receiving parts such that each of the plurality of LEDs is electrically connected to corresponding first and second conductive parts when the LEDs are respectively received in the LED receiving parts; and
e) separating the plurality of leads from the metallic substrate.

26. A method as claimed in claim 25, wherein step a) comprises:
a1) providing a plurality of base members formed from a thermal conductive material;
a2) providing a plurality of reflecting members an bonding the plurality of reflecting members to the plurality of base members with the leads interposed therebetween, wherein each of the LED receiving parts is formed through a corresponding reflecting member; and
a3) forming each of the lead mounting parts on one of a surface of a corresponding base member facing a corresponding reflecting member and a surface of a corresponding reflecting member facing a corresponding base member.

27. A method as claimed in claim 25, wherein step b) comprises:
b1) partially converting first predetermined areas of a metallic substrate into non-conductive areas through oxidation, thereby forming the non-conductive part and the first and second conductive parts of each of the plurality of leads, wherein the first and second conductive parts are insulated from each other;
b2) partially converting second predetermined areas of the metallic substrate into non-conductive areas through oxidation, thereby forming first and second electrode parts, for each LED package, which are electrically connected to a corresponding LED and which are insulated from the corresponding package body, and first and second external terminal parts, for each LED package, which are electrically connected to the first and second electrode parts and which are insulated from the corresponding package body;
b3) patterning and forming metallic layers on the first and second electrode parts, which are exposed to the outside of the metallic substrate; and
b4) partially removing the metallic substrate, such that the plurality of leads are spaced from each other.

28. A method as claimed in claim 26, wherein step c) comprises:
c1) bonding the plurality of leads to the lead mounting parts, respectively, by using an adhesive; and
c2) bonding the base members and the reflecting members to each other with the leads interposed therebetween.

29. A method as claimed in claim 28, wherein a conductive adhesive is used to bond the plurality of leads to the lead mounting parts and to bond the base members to the reflecting members.

30. A method as claimed in claim 27, wherein in step b4), the metallic substrate is punched such that a width of the first external terminal parts where they are in contact with the package body is different than a width of the second external terminal ports where they are in contact with the package body.
